(19) United States
(12) Patent Application Publication
(10) Pub. No.: US 2024/0235150 A1
(43) Pub. Date: Jul. 11, 2024

(54) SEMICONDUCTOR LASER DEVICE AND OPTOELECTRONIC COMPONENT

(71) Applicant: ams-OSRAM International GmbH, Regensburg (DE)

(72) Inventors: Johann RAMCHEN, Hausen (DE); Joerg Erich SORG, Regensburg (DE)

(73) Assignee: ams-OSRAM International GmbH, Regensburg (DE)

(21) Appl. No.: 18/561,496

(22) PCT Filed: May 17, 2022
(86) PCT No.: PCT/EP2022/063292

§ 371 Date: Nov. 16, 2023

(30) Foreign Application Priority Data
May 19, 2021 (DE) 102021113021.2

(51) Int. Cl. H01S 5/00; H01S 5/02208; H01S 5/042; H01S 5/323; H01S 5/42

(52) U.S. Cl. CPC H01S 5/0087; H01S 5/32341; H01S 5/423; H01S 5/02208; H01S 5/04256

(57) ABSTRACT

The invention relates to a semiconductor laser device a surface emitting semiconductor laser element having a GaN-containing compound semiconductor layer and a converter. The converter is adapted to convert a wavelength of laser radiation emitted from the surface emitting semiconductor laser element.

### CROSS-REFERENCE TO RELATED APPLICATIONS

The present application is a national stage entry from International Application No. PCT/EP2022/063292, filed on May 17, 2022, published as International Publication No. WO 2022/243294 A1 on Nov. 24, 2022, and claims priority to German Patent Application No. 10 2021 113 021.2, filed May 19, 2021, the disclosures of all of which are hereby incorporated by reference in their entireties.

### BACKGROUND

Surface-emitting semiconductor lasers are widely used as a light source of very high luminance. In general, efforts are being made to further develop GaN-based surface-emitting semiconductor lasers.

The object of the present invention is to provide an improved semiconductor laser device and an improved optoelectronic component.

### SUMMARY

According to embodiments, the object is achieved by the subject matter of the independent patent claims. Advantageous enhancements are defined in the dependent claims.

A semiconductor laser device comprises a surface-emitting semiconductor laser element comprising a GaN-containing compound semiconductor layer, and a converter adapted to convert a wavelength of the laser radiation emitted by the surface-emitting semiconductor laser element.

The semiconductor laser device may further comprise a carrier, wherein the converter is attached on the carrier, and the laser radiation is radiated through the carrier and the converter. For example, the carrier may be an optical element. For example, the converter may be directly attached on the optical element.

According to further embodiments, the semiconductor laser device may further comprise an optical element on a side of the converter facing away from the surface-emitting semiconductor laser element. For example, the optical element may be connected to the carrier.

The semiconductor laser device may further comprise a housing having a bottom portion and side portions, wherein the surface-emitting semiconductor laser element is disposed over the bottom portion and the side portions are attached laterally adjacent to the surface-emitting semiconductor laser element. For example, the side portions may protrude beyond the surface-emitting semiconductor laser element.

According to embodiments, the carrier for the converter may form a closure of the housing. According to further embodiments, the optical element may form a closure of the housing.

According to further embodiments, a semiconductor laser device comprises an array of a plurality of surface-emitting semiconductor laser elements comprising a GaN-containing compound semiconductor layer, and a converter adapted to convert a wavelength of the laser radiation emitted from the surface-emitting semiconductor laser elements.

For example, a single converter may be associated with the plurality of surface-emitting semiconductor laser elements. For example, the converter may vary locally.

According to further embodiments, the converter may comprise a plurality of converter regions and each of the plurality of surface-emitting semiconductor laser elements has a dedicated converter region associated with it.

The semiconductor laser device may further include driver electronics adapted to individually drive each of the plurality of surface-emitting semiconductor laser elements.

The semiconductor laser device may further comprise an optical apparatus on a side of the converter facing away from the array of semiconductor laser elements. The optical apparatus may comprise a plurality of optical elements. Each of the plurality of surface-emitting semiconductor laser elements may have a dedicated optical element associated with it.

For example, the converter may be directly disposed on the surface-emitting semiconductor laser element.

According to further embodiments, the semiconductor laser device may further comprise a bottom portion of a housing or a housing substrate to which the surface-emitting semiconductor laser element is attached, and an optical element that together with the bottom portion forms the housing of the semiconductor laser device.

An optoelectronic component comprises the semiconductor device described above. For example, the optoelectronic component may be selected from a micro-display apparatus, an illumination apparatus, and a motor vehicle headlight.

### BRIEF DESCRIPTION OF THE DRAWINGS

The accompanying drawings serve to provide an understanding of exemplary embodiments of the invention. The drawings illustrate exemplary embodiments and, together with the description, serve for explanation thereof. Further exemplary embodiments and many of the intended advantages will become apparent directly from the following detailed description. The elements and structures shown in the drawings are not necessarily shown to scale relative to each other. Like reference numerals refer to like or corresponding elements and structures.

FIG. 1A shows a schematic cross-sectional view of a semiconductor laser device according to embodiments.

FIG. 1B shows a horizontal cross-sectional view through a portion of the semiconductor laser device.

FIG. 1C shows a schematic cross-sectional view of a surface-emitting semiconductor laser element.

FIG. 2 shows a schematic cross-sectional view of a semiconductor laser device according to embodiments.

FIG. 3A shows a schematic view of a part of a workpiece for forming semiconductor laser device.

FIG. 3B shows an example of a semiconductor laser device.

FIG. 3C shows a schematic top view of elements of the semiconductor laser device.

FIG. 4A shows a schematic cross-sectional view of a semiconductor laser device according to embodiments.

FIGS. 4B and 4C illustrate an example of a wiring diagram for the semiconductor laser device.

FIG. 4D shows a schematic cross-sectional view of a semiconductor laser device according to further embodiments.

FIG. 5A shows a cross-sectional view of a workpiece for forming semiconductor laser device.

FIG. 5B shows a cross-sectional view of a workpiece for forming semiconductor laser device.

FIG. 6 shows a schematic view of an optoelectronic component according to embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since other exemplary embodiments may also exist and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may basically include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material, for example a GaAs substrate, a GaN-substrate, or an Si substrate, or of an insulating material, for example sapphire.

Depending on the intended use, the semiconductor may be based on a direct or an indirect semiconductor material. Examples of semiconductor materials particularly suitable for generating electromagnetic radiation include, without limitation, nitride semiconductor compounds by means of which, for example, ultraviolet, blue or longer-wave light may be generated, such as GaN, InGaN, AlN, AlGaN, AlGaInN, AlGaInBN; phosphide semiconductor compounds by means of which, for example, green or longer-wave light may be generated, such as GaAsP, AlGaInP, GaP, AlGaP; and other semiconductor materials such as GaAs, AlGaAs, InGaAs, AlInGaAs, SiC, ZnSe, ZnO, Ga₂O₃, diamond, hexagonal BN; and combinations of the materials mentioned. The stoichiometric ratio of the compound semiconductor materials may vary. Other examples of semiconductor materials may include silicon, silicon germanium, and germanium.

The term “substrate” generally includes insulating, conductive, or semiconductor substrates.

The term “vertical”, as used in this description, is intended to describe an orientation which is essentially perpendicular to the first surface of a substrate or a semiconductor body. The vertical direction may correspond, for example, to a direction of growth when layers are grown.

The terms “lateral” and “horizontal”, as used in the present description, are intended to describe an orientation or alignment which extends essentially parallel to a first surface of a substrate or a semiconductor body. This may be the surface of a wafer or a chip (die), for example.

The horizontal direction may, for example, be in a plane perpendicular to a direction of growth when layers are grown.

Typically, the wavelength of electromagnetic radiation emitted by a semiconductor laser element may be converted using a converter material containing a fluorescent substance or phosphor. For example, white light may be generated by combining a semiconductor laser element that emits blue light with a suitable phosphor. For example, the phosphor may be a yellow phosphor that, when excited by the light from the blue semiconductor laser element, is adapted to emit yellow light. For example, the phosphor may absorb a portion of the electromagnetic radiation emitted by the semiconductor laser element. The combination of blue and yellow light is perceived as white light. By admixing further phosphors adapted to emit light of a further wavelength, for example a red wavelength, the color temperature may be changed. According to further concepts, white light may be generated by a combination containing a blue emitting semiconductor laser element and a green and red phosphor. It is understood that a converter material may include several different phosphors, each emitting different wavelengths.

Examples of phosphors include metal oxides, metal halides, metal sulfides, metal nitrides, and others. These compounds may further contain additives that cause specific wavelengths to be emitted. For example, the additives may include rare earth materials. As an example of a yellow phosphor, YAG:Ce³⁺ (yttrium aluminum garnet activated with cerium (Y₃Al₅O₁₂)) or (Sr_{1.7}Ba_{0.2}Eu_{0.1})SiO₄ may be used. Other phosphors may be based on MSiO₄:Eu²⁺, wherein M may be Ca, Sr or Ba. A desirable conversion wavelength may be chosen by selecting the cations at an appropriate concentration. Many other examples of suitable phosphors are known.

According to applications, the phosphor material, such as a phosphor powder, may be embedded in a suitable matrix material. For example, the matrix material may comprise a resin or polymer composition such as a silicone resin or an epoxy resin. The size of the phosphor particles may, for example, be in a micrometer or nanometer range.

According to further embodiments, the matrix material may comprise a glass. For example, the converter material may be formed by sintering the glass, for example SiO₂ with further additives and phosphor powder, forming a phosphor in the glass (PiG).

According to further embodiments, the phosphor material itself may be sintered to form a ceramic. For example, as a result of the sintering process, the ceramic phosphor may have a polycrystalline structure.

According to further embodiments, the phosphor material may be grown to form a monocrystalline phosphor, for example using the Czochralski (Cz) process.

According to further embodiments, the phosphor material itself may be a semiconductor material having, in bulk or in layers, a suitable band gap for absorbing the light emitted by the semiconductor laser element and for emitting the desired conversion wavelength. In particular, this may be an epitaxially grown semiconductor material. For example, the epitaxially grown semiconductor material may have a band gap corresponding to an energy lower than that of the primary emitted light. Furthermore, multiple suitable semiconductor layers, each emitting light of a different wavelength, may be stacked on top of each other. One or more quantum wells, quantum dots, or quantum wires may be formed in the semiconductor material.

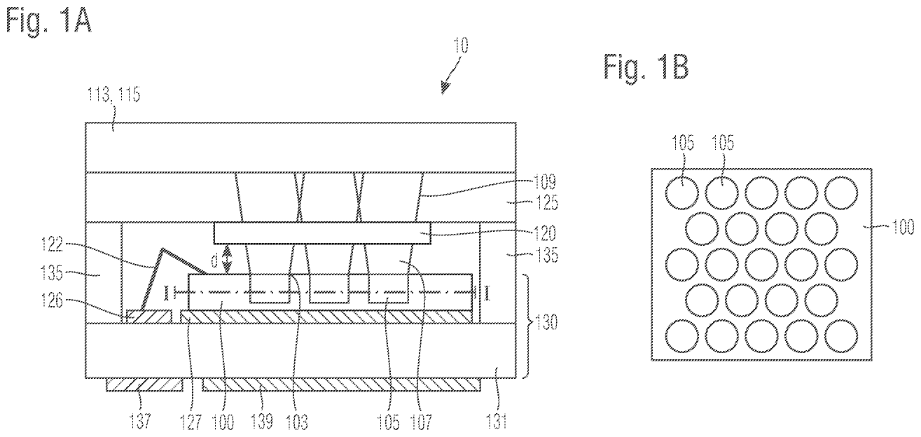

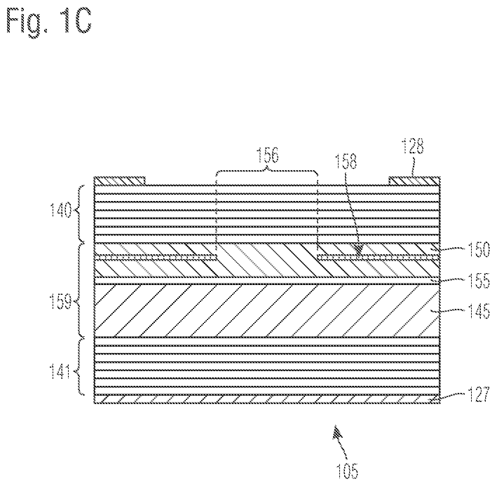

FIG. 1A shows a schematic cross-sectional view of a semiconductor laser device 10 according to embodiments. A semiconductor laser device 10 comprises a surface-emitting semiconductor laser element 105 comprising a GaN-containing compound semiconductor layer, and a converter 120. The converter 120 is adapted to convert a wavelength of the laser radiation 107 emitted by the surface-emitting semiconductor laser element 105.

As shown in FIG. 1A, a plurality of semiconductor laser elements 105 may be disposed over a laser substrate 100 or disposed in the laser substrate 100. For example, the laser substrate 100 may be a growth substrate on which individual layers are grown to form the semiconductor laser elements 105. However, according to further embodiments, the laser substrate 100 may be different from the growth substrate. For example, the semiconductor laser elements 105 may have been formed on a separate growth substrate and subsequently attached to the laser substrate 100. According to further embodiments, however, the term “laser substrate 100” may also refer to a semiconductor body in which the individual semiconductor laser elements 105 are formed.

The semiconductor laser device 10 may further comprise a housing 130. For example, the housing 130 may include a bottom portion 131 and one or more side portions 135. The laser substrate 100 may be disposed over the bottom portion 131. For example, the bottom portion 131 and the housing 130 may be made of a suitable semiconductor packaging material such as a ceramic or a suitable plastic.

For example, a conductive layer or portions of a conductive layer may be disposed on the bottom portion 131 and connected to the laser substrate 100. For example, the conductive layer or portions of the conductive layer may represent a first contact element 127 for contacting the semiconductor laser elements 105. For example, the first contact element 127 may be connected to a first contact pad 139 located on a side of the bottom portion 131 facing away from the first contact element 127. A second contact pad 137 may also be present, in isolation from the first contact pad 139, on a side of the bottom portion 131 facing away from the first contact element 127, and may be electrically connected to a second contact element 126. The second contact element 126 may, for example, be another portion of the conductive layer which is separate from the first contact element 127. It is possible that the second contact element 126 is, for example, not covered by the laser substrate 100. The second contact element 126 may, for example, be connected to a second semiconductor layer of the surface-emitting semiconductor laser element 105 through a first wiring 122. According to embodiments, individual surface-emitting semiconductor laser elements 105 may be individually driven so as to implement any desired illumination patterns.

Examples of the structure of surface-emitting semiconductor laser elements will be described in more detail below with reference to FIG. 1C.

For example, as shown in FIG. 1A, the side walls 135 of the housing may extend laterally along the laser substrate 100 in a vertical direction such that the laser substrate 100 with the surface-emitting laser elements 105 rests on the bottom portion 131 and is laterally enclosed by the side walls 135.

For example, the converter 120 may be disposed on a carrier 125. For example, the laser radiation 107 may be radiated through the carrier 125 and the converter 120. For example, the converter 120 may be disposed on the side of the carrier 125 facing the surface-emitting laser element 105. For example, the carrier 125 may form a top closure of the housing 130. In this manner, the carrier 125, the side portions 135 and the bottom portion 131 form a housing, and the converter 120 is disposed on the bottom surface of the housing cover. For example, the carrier 125 may be a glass or other transparent material having an anti-reflective coating. The converter 120 may be disposed on a top surface, a bottom surface, or within the carrier 125.

As illustrated in FIG. 1A, an optical element 113 or an optical apparatus 115 may be disposed over the carrier 125. For example, both the carrier 125 and the optical element 113 or optical apparatus 115 may have a planar major surface such that a compact shape is realized by combining the carrier 125, the converter 120, and the optical element 113 or optical apparatus 115. In any of the embodiments described, the optical element 113 may, for example, be a lens, such as a collimator lens, or an optically diffractive element, such as a grating element or the like. According to embodiments, a single optical element 113 may be provided for multiple or all of the surface-emitting semiconductor laser elements 105.

For example, an optical apparatus 115 may comprise a plurality of individual optical elements 113. For example, the optical apparatus 115 may be a lens array or the like. According to embodiments, an associated optical element 113 may be provided for each surface-emitting semiconductor laser element 105. Thus, by addressing the respective semiconductor laser elements 105 associated with a particular optical element 113, an application-specific beam shape may be generated.

The surface-emitting semiconductor laser element 105 comprises a GaN-containing compound layer. For example, the surface-emitting semiconductor laser element 105 may be capable of emitting laser radiation within a wavelength range of 400 to 470 nm. Accordingly, it is possible to achieve emission in a wide range of visible wavelengths using a suitable converter 120. Owing to the electromagnetic radiation being generated by surface-emitting semiconductor laser elements, it is possible to provide a light source that is as compact as possible and has the highest possible luminance. In particular, the individual surface-emitting semiconductor laser elements 105 ensure highly directional radiation. As a result, laser beams emitted by adjacent surface-emitting semiconductor laser elements 105 overlap only to a small extent, as indicated in FIG. 1A. In FIG. 1A, the converter 120 is arranged at a distance from the emission surface 103 of the surface-emitting semiconductor laser elements. For example, the distance d may be 500 nm to 100 μm, such as 1 to 100 μm.

FIG. 1B shows an example of an array of the surface-emitting semiconductor laser elements 105 over the laser substrate 100. For example, the view of FIG. 1B may be a horizontal cross-sectional view between I and I′ in FIG. 1A. Any desired array pattern may be implemented in this context. For example, FIG. 1B shows a checkerboard pattern of the surface-emitting semiconductor laser elements 105. According to further embodiments, the surface-emitting semiconductor laser elements may also be arranged in rows and columns.

FIG. 1C shows an example of a surface-emitting laser element 105 that may be part of the described semiconductor laser device 10. The surface-emitting laser element 105 comprises a first resonator mirror 141, a second resonator mirror 140, and an optical resonator 159 between the first resonator mirror 141 and the second resonator mirror 140. The optical resonator 159 extends in a vertical direction. The first resonator mirror 141 may include alternately stacked first layers of a first composition and second layers of a second composition. For example, when dielectric layers are used, they may have alternating high (n>1.7) and low refractive indices (n<1.7) and may be formed as Bragg reflectors. According to further embodiments, the first resonator mirror 141 may also comprise semiconductor layers. In this case, semiconductor layers having a high refractive index (n>3.3) and semiconductor layers having a low refractive index (n<3.3) may be alternately arranged. For example, the layer thickness may be λ/4 or a multiple of λ/4, wherein X indicates the wavelength of the light to be reflected. For example, the first resonator mirror 141 may comprise from 2 to 50 different layers. A typical layer thickness of the individual layers may be about 30 to 90 nm, for example about 50 nm. The layer stack may further include one or two or more layers that are thicker than about 180 nm, for example thicker than 200 nm. For example, the first resonator mirror 141 may have a total reflectivity of 99.8% or greater for the laser radiation.

Layers of the first resonator mirror 141 may be doped, for example, to exhibit a first conductivity type, such as n-type. A first semiconductor layer 145 of a first conductivity type, for example n-type, may be disposed over the first resonator mirror 141. Furthermore, the semiconductor layer stack may comprise a second semiconductor layer 150 of a second conductivity type, for example p-type. An active region 155 may be disposed between the first semiconductor layer 145 and the second semiconductor layer 150.

The active zone 155 may, for example, comprise a pn junction, a double heterostructure, a single quantum well structure (SQW, single quantum well), or a multiple quantum well structure (MQW, multi quantum well) for generating radiation. The term “quantum well structure” does not imply any particular meaning here with regard to the dimensionality of the quantization. Therefore, it includes, among other things, quantum wells, quantum wires and quantum dots as well as any combination of these structures. A suitable insulating layer 158 extends in each case from the edge of the semiconductor laser element 105 toward the center of the semiconductor laser element 105, leaving a conductive region in the central region. An aperture 156 for conducting current is formed through the regions of the insulating layer 158. The first semiconductor layer 145 is electrically connectable via a first contact element 127, and the second semiconductor layer 150 is electrically connectable, for example, via a second contact element 126 (not shown in FIG. 1C) and, if necessary, a surface contact element 128. A diameter of an emitted laser beam may be about 10 μm, for example.

The first and second semiconductor layers 145, 150 and active region layers 150 may each contain GaN or a GaN-containing compound semiconductor material. For example, an emission wavelength of the surface-emitting semiconductor laser element may be in a range of 400 to 470 nm. The surface-emitting semiconductor laser element 105 is capable of emitting narrowband electromagnetic radiation. The emission wavelength of a VCSEL, in particular, is very stable with respect to temperature and shows only little temperature-dependent variation. Accordingly, it is possible to use a converter for the surface-emitting semiconductor laser element 105 that has only a narrow absorption range. If a converter matched to the wavelength of the surface-emitting semiconductor laser element 105 is used, a thermal load is reduced.

FIG. 1C depicts an illustrative example of a surface-emitting semiconductor laser element 105. It is understood that components of the surface-emitting semiconductor laser element 105 may be modified. According to further embodiments, the surface-emitting semiconductor laser element 105 may be implemented in other ways. For example, the surface-emitting semiconductor laser element 105 may also be implemented as a HCSEL (“horizontal cavity surface-emitting laser”), i.e., as a surface-emitting laser having a horizontal resonator. Alternatively, the surface-emitting semiconductor laser element 105 may be realized as a PCSEL (“photonic crystal surface-emitting laser”), i.e., a semiconductor laser in which, for example, a photonic crystal is provided instead of resonator mirrors.

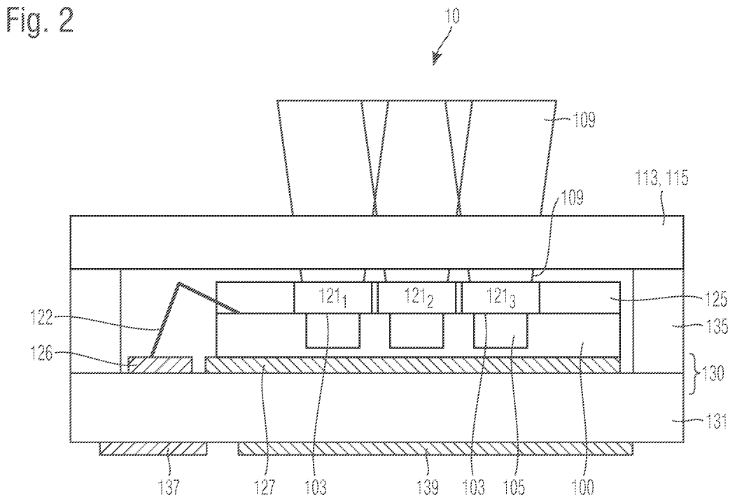

FIG. 2 shows a schematic cross-sectional view of a semiconductor laser device 10 according to further embodiments.

Differing from embodiments shown in FIG. 1A, the converter 120 is in this case disposed directly on the emission surface 103 or a surface of the surface-emitting semiconductor laser elements 105. For example, as shown in FIG. 1A, the converter 120 may be formed as one element associated with a plurality of laser elements 105. However, according to further embodiments, each laser element 105 may also be associated with a separate dedicated converter region 121₁, 121₂, 121₃, as shown in FIG. 2. For example, the individual converter regions 121ᵢ may be integrated into a carrier 125. The individual converter regions 121ᵢ may be identical or different from each other. For example, the carrier may contain a material of high thermal conductivity. Cavities for the converter material may be formed in the carrier 125. Alternatively, patches of converter material may be formed on a planar carrier, for example applied by screen printing or the like. In this manner, it is possible for the heat generated by the conversion to be dissipated locally.

For example, in FIG. 2, the optical element 113 or optical apparatus 115 may form a top closure of the housing 130. The optical element 113 or optical apparatus may be connected to side portions 135 of the housing. According to further embodiments, the carrier 125 may be omitted. According to further embodiments, a lateral extent of the carrier 125 may be smaller than that of the bottom portion 131 of the housing 130.

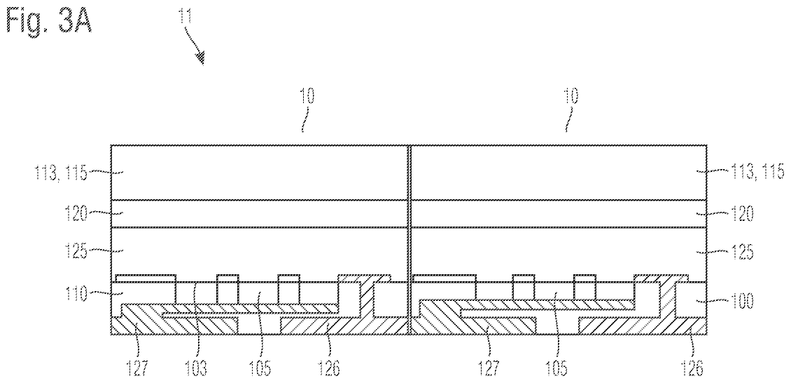

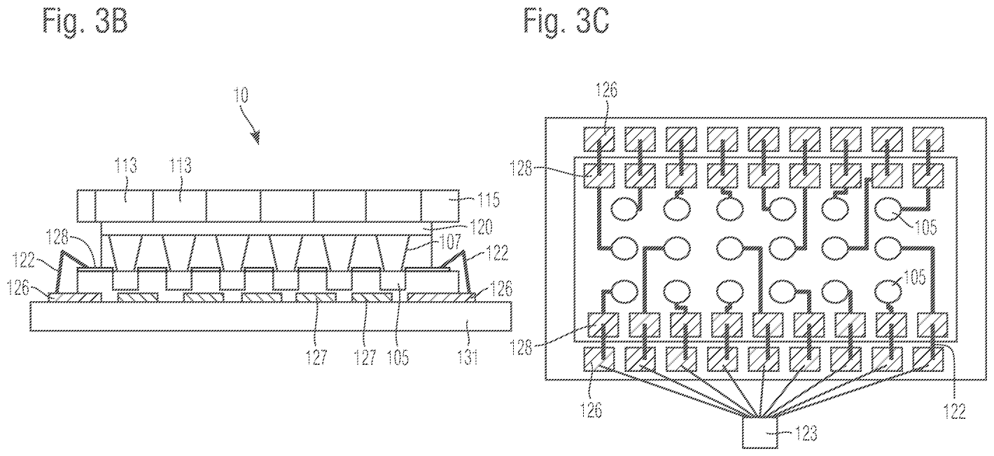

FIG. 3A shows a schematic cross-sectional view of a portion of a workpiece 11 for forming semiconductor apparatus 10 according to embodiments. As indicated in FIG. 3A, a plurality of wafer-level semiconductor laser device 10 may be formed by common processing steps. For example, a semiconductor laser device 10 may each include a plurality of surface-emitting semiconductor laser elements 105 that are disposed over a suitable laser substrate 100 and electrically connected. The converter 120 may be connected to the optical element 113 or the optical apparatus 115. For example, the converter 120 may be spaced apart from the surface-emitting semiconductor laser elements 105 or may be adjacent to an emission surface 103. According to embodiments, a carrier 125 may additionally be disposed over the surface-emitting semiconductor laser elements 105. The carrier 125 may be, for example, a glass having an anti-reflective layer. A converter 120 may be disposed on one side of the carrier 125. According to further embodiments, the converter 120 may also be incorporated or integrated into the carrier 125. For example, the carrier 125 may be a silicate with an admixture of a suitable converter 120. According to embodiments, the carrier 125 may be adjacent to an emission surface 103 of the surface-emitting semiconductor laser elements 105.

For example, the or some of the surface-emitting semiconductor laser elements 105 of a semiconductor laser device 10 may be driven together. Each semiconductor laser device 10 may have associated therewith a separate converter element 120 that, for example, effects conversion to any respectively different color. Also, each semiconductor laser device 10 may have an individual optical element 113 of an optical apparatus 115 associated therewith. In this manner, a very specific beam shape may be generated for each semiconductor apparatus 10.

According to embodiments, the converters 120 may also vary locally so that a color is emitted on the right side of a semiconductor laser device different from that emitted on the left side of a semiconductor laser device.

FIG. 3B shows another implementation of a semiconductor laser device 10 according to embodiments. In principle, the semiconductor laser device 10 shown in FIG. 3B is similar in structure to those shown in FIG. 1A or 2. However, it is possible in this case to selectively drive individual surface-emitting semiconductor laser elements 105 by means of an appropriate wiring structure. Accordingly, for example, a plurality of first contact elements 127 may be arranged over the bottom portion 131 to effect driving of the individual surface-emitting semiconductor laser elements. The surface-emitting semiconductor laser elements 105 may further be driven via surface contact elements 128 electrically connected to the second contact elements 126, for example, via first wiring 122. Each of the surface contact elements 128 may be disposed on a top surface of the laser substrate 100. FIG. 3B further illustrates an optical apparatus 115 comprising a plurality of optical elements 113. Other elements are as described with reference to FIGS. 1A and 2. In this manner, any desired illumination pattern may be implemented.

FIG. 3C shows a view of an array of the individual surface-emitting semiconductor laser elements 105 and associated circuit and wiring structures. As may be seen, the individual surface-emitting semiconductor laser elements 105 may each be driven individually via second contact elements 126 and surface contact elements 128. However, according to further embodiments, wiring patterns other than those illustrated in FIG. 3C may be used. For example, the second contact elements 126 may each be connected to the surface contact elements 128 via first wiring 122. FIG. 3C further illustrates drive electronics 123 suitable for individually driving each of the plurality of surface-emitting semiconductor laser elements.

For example, the semiconductor laser device 10 illustrated in FIGS. 3B and 3C may be part of a motor vehicle headlight. For example, the motor vehicle headlight may track moving objects by selectively turning on and off the individual surface-emitting semiconductor laser elements 105. Due to the low beam divergence of the emitted laser radiation, no crosstalk occurs and higher contrast may be achieved.

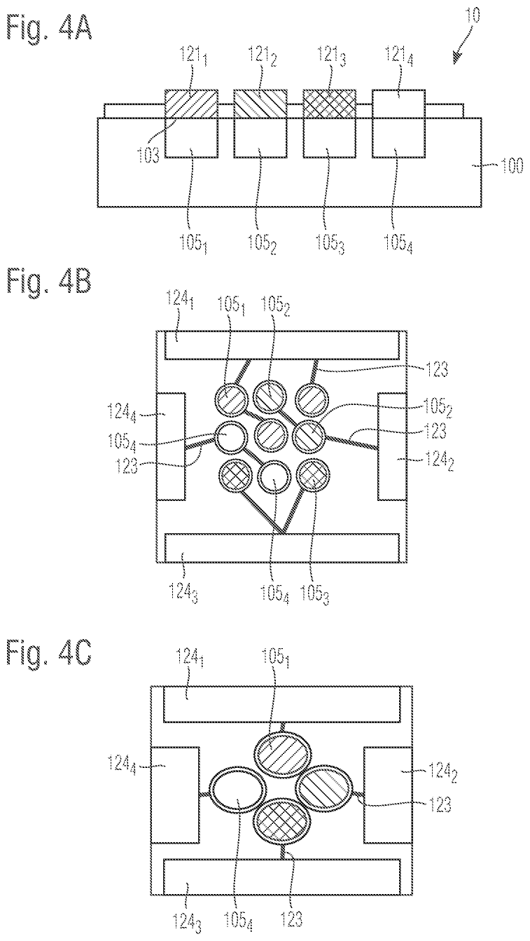

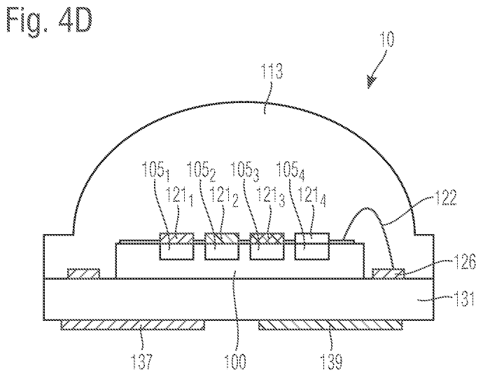

FIG. 4A illustrates a semiconductor laser device according to further embodiments. For example, as illustrated in FIG. 4A, the semiconductor laser device 10 may include a plurality of surface-emitting semiconductor laser elements 105₁, 1051₂, . . . , 105ₙ. A single converter element 121₁, 121₂, . . . , 121ₙ is associated with each of the individual surface-emitting semiconductor laser elements. For example, the individual converter elements 121₁, 121₂, . . . , 121ₙ may have different compositions and/or layer thicknesses and may thus effect conversion to different colors. The individual converter elements 121ᵢ may be disposed directly over the surface-emitting semiconductor laser elements and may be directly adjacent to an emission surface 103, for example. The individual surface-emitting semiconductor laser elements 105ᵢ may be disposed over a laser substrate 100 or within the laser substrate 100.

FIG. 4B shows an example of a wiring scheme for electrically contacting the individual surface-emitting semiconductor laser elements 105₁, 1051₂, . . . , 105ₙ. For example, one contact pad 124₁, 124₂, . . . , 121₄ may each be connected to one corresponding laser element 105₁, 1051₂, . . . , 105ₙ. Thus, emission by the corresponding laser element 105₁, 1051₂, . . . , 105, may be effected. In this manner, by suitably driving the corresponding contact pads, the semiconductor laser device 10 may radiate in white at a desired color temperature, green, red or blue.

FIG. 4C shows a top view of the semiconductor laser device according to further embodiments, in which alternative wiring is implemented.

FIG. 4D shows a schematic view of a semiconductor laser device 10 in which the components shown in FIG. 4A are further disposed on a bottom portion 131 of a housing and correspondingly connected to a second contact element 126. An optical element 113 is disposed over the surface-emitting semiconductor laser elements. For example, the optical element 113 may be implemented by a suitably molded or cast silicone element. For example, a silicone encapsulant may be molded into a lens shape. In this case, the optical element 113 together with the bottom portion 131 may constitute a housing of the semiconductor laser device 10.

When using multiple surface-emitting semiconductor laser elements 105ᵢ, for example as shown in FIGS. 4A to 4D, each associated with different converter regions 120i, a light source that emits in different colors or color temperatures when appropriately driven may be realized.

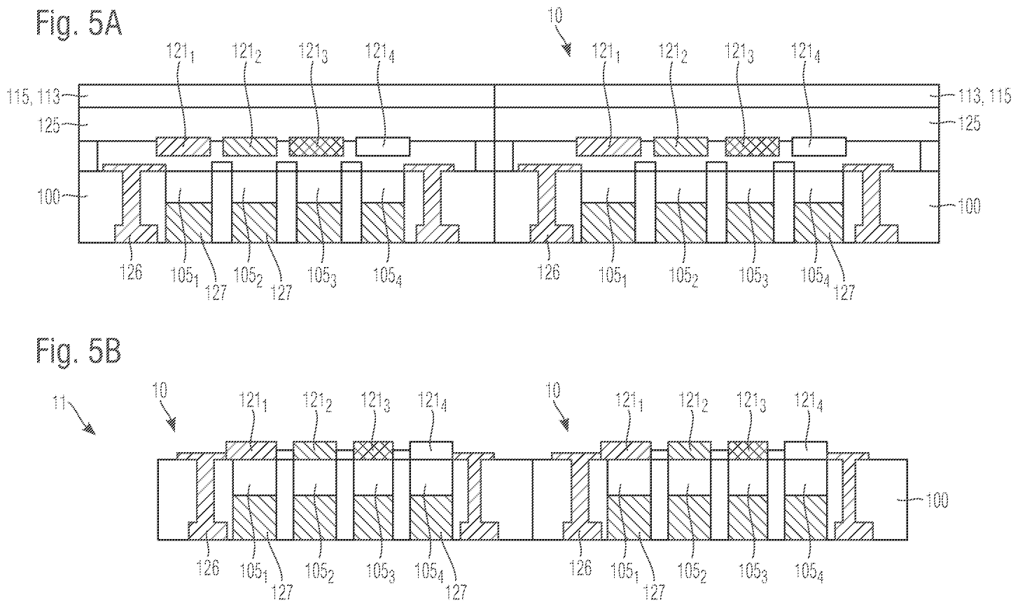

FIG. 5A shows a schematic cross-sectional view of a portion of a workpiece 11 for forming semiconductor apparatus 10 according to embodiments. As indicated in FIG. 5A, a plurality of wafer-level semiconductor laser device 10 may be formed by common processing steps. In this regard, as shown in FIG. 5A, similar to what is described with reference to FIG. 1A, various converter regions 121ᵢ may be attached to a substrate 125. In this regard, the individual converter regions 121ᵢ may each be aligned with the surface-emitting semiconductor laser elements 105 and may locally overlap with a respective surface-emitting semiconductor laser element 105. Since the individual surface-emitting semiconductor laser elements 105 are capable of emitting highly directional radiation, there is no crosstalk between adjacent surface-emitting semiconductor laser elements 105, so that when a particular surface-emitting semiconductor laser element 105 is activated, radiation into adjacent converter regions 121ᵢ may be reduced or prevented. The carrier 125 for the converter regions 121ᵢ, in combination with the laser substrate 100, may each form a housing for the semiconductor laser device 10. For example, the carrier 125 may include a material having a high thermal conductivity. Cavities for the converter material may be formed in the carrier 125. Alternatively, patches of converter material may be formed on a planar carrier, for example applied by screen printing or the like. In this manner, it is possible for the heat generated by the conversion to be dissipated locally.

An optical element 113 or optical apparatus 115 may be provided on a surface of the substrate 125 facing away from the surface-emitting laser elements.

By selectively addressing individual surface-emitting semiconductor laser elements, a light source with different colors may be realized.

According to further embodiments, differing from embodiments described with reference to FIG. 5A, the converter regions 121ᵢ may also be disposed directly on the individual surface-emitting semiconductor laser elements 105ᵢ and directly adjacent to an emission surface 103. This is illustrated, for example, in FIG. 5B, which shows a workpiece 11 for forming semiconductor apparatus 10 according to embodiments. As indicated in FIG. 5B, a plurality of wafer-level semiconductor laser device 10 may be formed by common processing steps. For example, the individual converter regions may be formed directly on the associated surface-emitting semiconductor laser elements 105 by screen printing.

According to embodiments, an optical element 113 or optical apparatus 115 may be additionally arranged, for example as similarly illustrated in FIG. 4D or 2. In a similar manner as previously described, the individual surface-emitting laser elements 105ᵢ of the individual semiconductor laser device may be individually driven to emit corresponding color patterns.

As has been described, by combining surface-emitting semiconductor laser elements having a GaN-containing compound semiconductor layer with suitable converters, a light source may be provided which is suitable for emitting electromagnetic radiation in any color tones and also, for example, in white with different color temperatures. For example, by a suitable drive, any colors or color temperatures as well as different illumination patterns may be set.

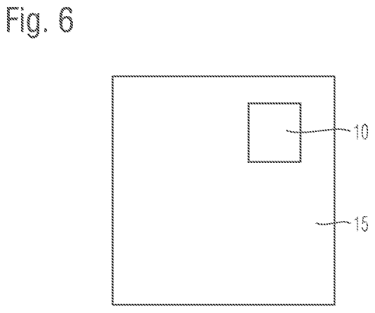

FIG. 6 shows a schematic view of an optoelectronic component 15. The optoelectronic component 15 includes the semiconductor laser device 10 described above. The optoelectronic component may, for example, be a high-luminosity micro-display apparatus, a high-power lighting apparatus, such as for events or stages or film studios, a high-luminosity lighting apparatus for buildings, or a motor vehicle headlight.

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

1. A semiconductor laser device comprising:
a surface-emitting semiconductor laser element comprising a GaN-containing compound semiconductor layer; and
a converter adapted to convert a wavelength of the laser radiation emitted by the surface-emitting semiconductor laser element, wherein the converter is directly attached to the surface-emitting semiconductor laser elements,
further comprising a housing comprising a bottom portion and side portions, wherein the surface-emitting semiconductor laser element is disposed over the bottom portion, and the side portions are disposed laterally adjacent to the surface-emitting semiconductor laser element, and
further comprising an optical element forming a closure of the housing.

2. The semiconductor laser according to claim 1, further comprising a carrier, wherein the converter is disposed on the carrier, and the laser radiation is radiated through the carrier and the converter.

3. The semiconductor laser according to claim 2, wherein the carrier is an optical element.

4. The semiconductor laser according to claim 1, further comprising an optical element on a side of the converter facing away from the surface-emitting semiconductor laser element.

5. The semiconductor laser according to claim 2, further comprising an optical element on a side of the converter facing away from the surface-emitting semiconductor laser element, wherein the optical element is connected to the carrier.

6-8. (canceled)

9. A semiconductor laser device comprising:
an array of a plurality of surface-emitting semiconductor laser elements comprising a GaN-containing compound semiconductor layer; and
a converter adapted to convert a wavelength of the laser radiation emitted by the surface-emitting semiconductor laser elements, wherein the converter is directly attached to the surface-emitting semiconductor laser elements,
further comprising a bottom portion of a housing to which the surface-emitting semiconductor laser element is attached, and an optical element which together with the bottom portion forms the housing of the semiconductor laser device.

10. The semiconductor laser device according to claim 9, wherein a single converter is associated with the plurality of surface-emitting semiconductor laser elements.

11. The semiconductor laser device according to claim 10, wherein the converter varies locally.

12. The semiconductor laser device according to claim 9, wherein the converter comprises a plurality of converter regions and each of the plurality of surface-emitting semiconductor laser elements has a dedicated converter region associated therewith.

13. The semiconductor laser device according to claim 9, further comprising driver electronics adapted to individually drive each of the plurality of surface-emitting semiconductor laser elements.

14. The semiconductor laser device according to claim 9, further comprising an optical apparatus on a side of the converter facing away from the array of semiconductor laser elements.

15. The semiconductor laser device according to claim 14, wherein the optical apparatus comprises a plurality of optical elements and each of the plurality of surface-emitting semiconductor laser elements has a dedicated optical element associated therewith.

16-17. (canceled)

18. An optoelectronic component comprising a semiconductor laser device according to claim 1.

19. The optoelectronic component according to claim 18, selected from a micro-display apparatus, an illumination apparatus, and a motor vehicle headlight.
